(19) United States
(12) Patent Application Publication
(10) Pub. No.: US 2006/0016786 A1
(43) Pub. Date: Jan. 26, 2006

(54) Method and apparatus for removing SiC or low k material film

(76) Inventors: Bing-Yue Tsui, Hsinchu (TW); Kuo-Lung Fang, Judung Jen (TW); Yuan-Hsin Li, Jungli City (TW); Chih-Hung Wu, Hsinchu (TW)

Correspondence Address: PERKINS COIE LLP, P.O. BOX 2168, MENLO PARK, CA, 94026, US

(21) Appl. No.: 10/899,594

(22) Filed: Jul. 26, 2004

(51) Int. Cl. B44C 1/22; H01L 21/306

(52) U.S. Cl. 216/83; 216/87; 216/95; 216/99; 438/745; 156/345.11

(57) ABSTRACT

The present invention disclosed a method and apparatus for removing a SiC or a low k dielectric film, wherein the SiC or low k dielectric film is deposited on a substrate. The method comprising: Process the low k dielectric film or SiC film with high temperature oxidation, such as wet oxidation or dry oxidation, to transform the film into an oxide film layer, then remove the oxide film layer by wet etching. The present invention also disclosed an apparatus to perform the process, comprising: a high temperature processing unit such as a high temperature furnace, and a wet etching unit such as a wet bench or a single wafer spin etching processor. These units may form as a single apparatus, a cluster tool or separate tools.

### BACKGROUND OF THE INVENTION

1. Field of the invention

The present invention relates to a method and apparatus for removing silicon carbide (SiC) or low dielectric (low k) material film, In particular, the present invention relates to a method and apparatus to remove the SiC or low k material thin film on recycling control-wafers by oxidation and etching.

2. Description of Relative Prior Art

SiC and low k dielectric films are widely used in interconnection of the back end process of semiconductor manufacturing and are not easy to etch by chemical etching. The control-wafer can not be recycled by removing the deposited SiC or low k dielectric film from the substrate by wet etching. Traditionally the SiC or low k dielectric film is removed by chemical mechanical polishing (CMP). Though it is simple, the cost is high and need a longer time to remove it. Furthermore, part of the substrate may also be consumed. This will decrease the lifetime of the substrate, and may affect the recycling efficiency of the control-wafers.

In the Taiwanese patent publication No. 464977, proposed a SiC removing method. After forming a layer of silicon nitride (Si₃N₄) and a layer of SiC film, the SiC is etched with high density plasma, till the remaining thickness of the Si₃N₄ approaches 500 Å, then using the remaining Si₃N₄ to be the under-layer for the deposition of another layer of SiC film. Wherein the etch time of the high density plasma is 1 to 3 minutes longer then the deposition time of the SiC. The operation condition of the high density plasma is the temperature of the reaction chamber, which is between 350° C. to 450° C., the pressure is between 4 mtorr to 8 mtorr, the flow rate of the hydrogen is between 300 sccm to 800 sccm, the frequency and power of the low frequency RF power source is 1 MHz, 3000 watts. Also proposed a forming method of the SiC control-wafer, wherein the remaining Si₃N₄ layer is removed by acidic liquid, which includes 49% of HF. It also proposes a method for recycling the silicon wafer by repeat forming and removing steps of SiC. The disadvantage of this method may need a long process time and a lot of power consumption. High cost and the need of Si₃N₄ layer are additional drawbacks.

The Taiwanese patent publication No. 465022 proposed a dielectric thin film removing method. By using oxygen plasma to treat the control-wafer to form a dielectric film of silicon-rich oxide layer, then forms a layer of dielectric thin film, and then removes the dielectric thin film by immerse the silicon control-wafer in a solution of NH₄OH and H₂O₂ to transform the surface of the dielectric film to be hydrobolic, finally removes the dielectric film by HF solution to remove the film. The disadvantage of this method is that the growth of an extra silicon dioxide, which increases the dielectric constant; furthermore, this method may not be applied to other dielectric film from a control-wafer.

### OBJECT OF THE INVENTION

It is therefore an object of the invention to provide a method and apparatus to remove the silicon carbide (SiC) or low dielectric constant (low k) dielectric film from a control-wafer, which need a shorter time, less power and lower cost to remove the films.

It is another object of the invention to provide a method and apparatus to remove SiC or low k dielectric film from a control-wafer, to increase the lifetime of the control-wafer.

It is yet a further object of the invention to provide a method and apparatus to remove SiC or low k dielectric film from a control-wafer, which may apply to most of the low k dielectric.

### DISCLOSURE OF THE INVENTION

In order to achieve the above object, a first aspect of the present invention teaches a method and apparatus for removing the silicon carbide (SiC) or low dielectric constant (low k) material film from a control-wafer, wherein the SiC or the low k dielectric film is formed on a substrate. The method is mainly by treating the SiC or the low k dielectric film with a high temperature oxidation to transform the SiC or the low k dielectric film to an oxide layer, and then remove the oxide layer by wet etching.

Said high temperature oxidation may be wet oxidation or dry oxidation, and can completely oxidize the SiC or the low k dielectric film at temperatures above 400° C. The high temperature oxidation process of the present invention, for example, is a high temperature furnace, a rapid thermal processing (RTP). The oxide may be removed by etching with HF contained solutions, such as buffered HF. It may also be dry etching, such as plasma etching.

Said substrate can be silicon substrate or other substrate of suitable material. Said material of low k dielectric may be carbon doped oxide (CDO), porous carbon doped oxide (PCDO), silicon-base inorganic material such as HSQ, MSQ, CVD-Black Diamond, CVD-Carol, Orion™ flowfill™, etc, and the same silicon-base inorganic material with nano-hole structure. Said oxide layer generally is silicon dioxide.

Another aspect of the present invention teaches an apparatus for removing said silicon carbide or low k dielectric film, said apparatus mainly including a high temperature processing unit such as a high temperature furnace or a rapid thermal processing (RTP), which providing the SiC or the low k film enduring a high temperature process to transform the film into oxide, also including an etching unit with etch solution that can remove said oxide.

Said high temperature processing unit is a high temperature furnace or RTP equipment, and said etching unit is a wet bench, such as a single wafer spin etching and cleaning bench, a batch etching and cleaning bench or a plasma dry etching apparatus. Said high temperature processing unit and said etching unit may be installed as one apparatus or separately installed, or formed a cluster tools.

### BRIEF DESCRIPTION OF THE DRAWINGS

The foregoing and other advantages of the invention will be more fully understood with reference to the description of the best embodiment and the drawing wherein:

FIG. 1 to FIG. 3 illustrates the process of the method for removing all the silicon carbide or low k dielectric film of the present invention.

FIG. 4 to FIG. 6 illustrates the process of the method for removing part of the SiC or the low k dielectric film of the present invention.

### DISCRIDTION OF THE PREFERRED EMBODIMENTS

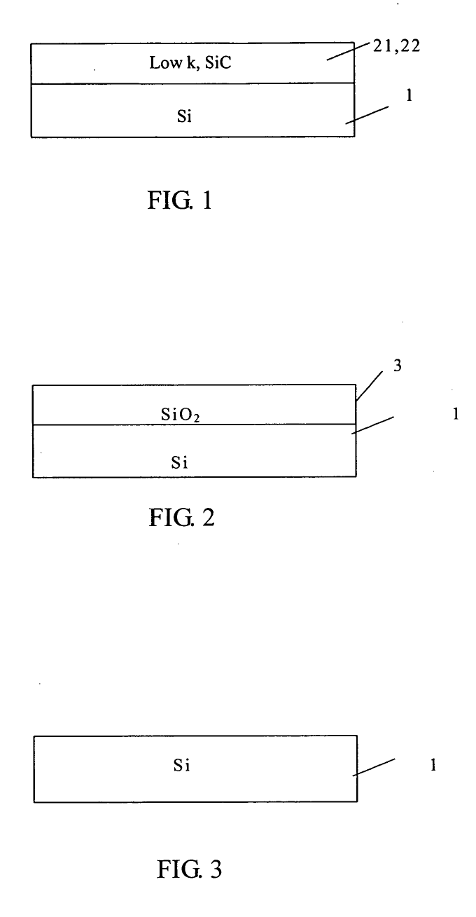

FIG. 1 to FIG. 3 illustrate the process of the method for removing all the silicon carbide or low k dielectric film of the present invention, wherein the low k dielectric film 21 or the SiC layer 22 is formed on a substrate 1. As shown in FIG. 1, after treating with high temperature oxidation, the low k dielectric film 21 or the SiC layer 22 is transformed into silicon dioxide layer 3, as shown in FIG. 2. Then the silicon dioxide layer 3 is removed by wet etching, as shown in FIG. 3, such that the silicon substrate can be used again.

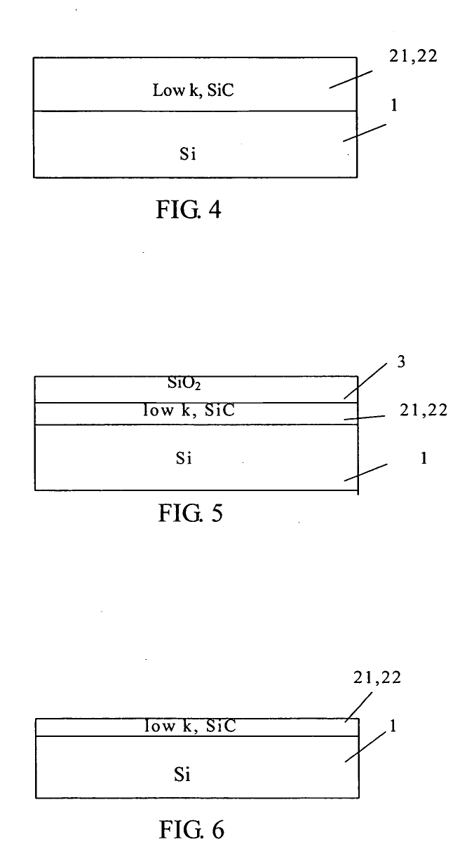

FIG. 4 to FIG. 6 illustrate the process of the method for removing part of the SiC or the low k dielectric film of the present invention, wherein the low k dielectric film 21 or the SiC layer 22 is deposited on a silicon control-wafer 1, as shown in FIG. 4, After oxidation, part of the low k material film 21 or the SiC layer 22 is transformed into silicon dioxide layer 3, as shown in FIG. 5, this silicon dioxide layer is removed by etching, as shown in FIG. 6.

The dry oxidation or wet oxidation transforms the SiC into SiO₂, The oxidation reaction equations of the SiC is as follow:
SiC+2O₂→SiO₂+CO₂ (1)
SiC+4H₂O→SiO₂+CO₂+4H₂ (2)

From the experiment results, we know that the oxidation rate of SiC in wet oxide is faster than that in dry oxide. The thickness of the oxide can be modeled with the Deal-Grove model as the following equation:
X₀²+AX₀=Bt (3)

Where X₀ is the thickness of the oxide layer, t is the oxidation time, A and B are constant. B is also a parabolic constant of oxidation (i.e. when X₀ is thick, X₀²=Bt), B/A is the linear constant of oxidation (i.e. when X₀ is thin, X₀=Bt/A). Refer to FIG. 7 and FIG. 8, FIG. 7 illustrates the relation between the thickness (in nm) of dry oxidation and the required oxidation time per unit thickness t/X₀ (in min/nm); FIG. 8 illustrates the relation between the thickness (in nm) of wet oxidation and the required oxidation time per unit thickness t/X₀ (in min/nm). From equation (3), the value of A and B can be obtained from these charts of FIG. 7 and FIG. 8.

### Embodiment 1

Supplies dry oxide in an oxidation furnace to perform oxidation with four different temperatures. The results are shown in FIG. 7, the values of A and B are obtained as in Table 1

TABLE 1
Results of dry oxidation of SiC

| Temperature | 550° C. | 650° C. | 750° C. | 850° C. |
|---|---|---|---|---|
| A(nm) | 4.28 | 15.17 | 15.57 | 32.05 |
| B(nm) | 7.60 | 23.64 | 44.31 | 127.56 |

From table 1, even by dry oxidation, at temperature of 550° C., the value of B is still as high as 7.6, which is faster than the oxidation of silicon.

### Embodiment 2

Supplied wet oxide in an oxidation furnace to process oxidation with three different temperature, the results are shown in FIG. 8, the values of A and B are obtained as in Table 2

TABLE 2
Results of wet oxidation of SiC

| Temperature | 650° C. | 750° C. | 850° C. |
|---|---|---|---|
| A(nm) | 116.18 | 78.47 | 64.27 |
| B(nm) | 406.73 | 574.53 | 1379.29 |

Form table 2, the oxidation rate of wet oxidation is much higher than that of dry oxidation. Although the oxidation temperature is above 650° C. in the present embodiment, it can obtain an efficient oxidation rate as at temperature low as 400° C.

### Embodiment 3

By using a vertical furnace of ASM advance 400 to perform wet (H₂+O₂) oxidation, the flow rate of H₂ is 4 slm, the flow rate of 02 is 4 slm, the temperature is 950° C., the thickness of the SiC is 70 nm, oxidation time is 2 hours, the SiC is completely oxidized, the silicon substrate is also partly oxidized. The results are shown in table 3:

TABLE 3
The oxidation Results of a 70 nm SiC film oxidizing at 950° C.

| method | SiC#1 | SiC#2 | SiC#3 | SiC#4 | Si |
|---|---|---|---|---|---|
| SiC thickness (nm) | 70.0 | 70.0 | 70.0 | 70.0 | 0 |
| SiC thickness (nm) | 376.9 | 389.5 | 409.9 | 390.5 | 350.5 |
| Tolerance | 3.37 | 6.41 | 6.70 | 7.89 | 12.40 |
| Particles (>0.2 μm) | 36 | 43 | 112 | 73 | 132 |

The number of particles in this table is the particle on the surface of the wafer after etching, and is measured by a KLA Tencor SP1. The particle is less then the cleanliness of a clean room.

The surface of the silicon substrate is observed by an atomic force microscopy (ASM) after etching, it shows that the surface is very smooth. The average root-mean-square roughness is as low as 0.300 nm.

### Embodiment 4

The low dielectric constant materials of carbon doped oxide (CDO) and porous carbon doped oxide (PCDO) are oxidized by dry oxidation in an oxidation furnace. 360 nm of CDO and 180 nm of PCDO are oxidized at 950° C., then is removed with dilute HF.

The etching process of the present invention can be performed in a single wafer spin etching and cleaning bench or a wet etching apparatus.

Although specific embodiments of the invention have been disclosed, it will be understood by those having skill in the art that minor changes can be made to the form and details of the specific embodiments disclosed herein, without departing from the spirit and the scope of the invention. The embodiments presented above are for purposes of example only and are not to be taken to limit the scope of the appended claims.

What is claimed is:

1. A method for removing silicon carbide (SiC) or low dielectric constant (low k) dielectric film, wherein said SiC and low k dielectric film are formed on a substrate, the method comprising the following steps:
Processing the SiC or low k dielectric film with high temperature oxidation to transform into an oxide layer; and
Removing the oxide layer with etch solution.

2. The method as recited in claim 1, wherein said low k dielectric film is carbon doped oxide (CDO).

3. The method as recited in claim 1, wherein said low k dielectric film is porous carbon doped oxide (PCDO).

4. The method as recited in claim 1, wherein said low k dielectric film is silicon-base inorganic material (HSQ, MSQ, CVD-Black Diamond, CVD-coral, Orio™, flowfill™, etc).

5. The method as recited in claim 1, wherein said low k dielectric film is silicon-base inorganic with nano pore structure.

6. The method as recited in claim 1, wherein said high temperature oxidation is wet oxidation.

7. The method as recited in claim 1, wherein said high temperature oxidation is dry oxidation.

8. The method as recited in claim 1, wherein said low k material film is oxidized completely.

9. The method as recited in claim 1, wherein said high temperature oxidation is processed at a temperature higher then 550° C.

10. The method as recited in claim 1, wherein said high temperature oxidation is processed at a temperature higher then 400° C.

11. The method as recited in claim 1, wherein said high temperature oxidation is performed in a rapid thermal processing (RTP) system.

12. The method as recited in claim 1, wherein said high temperature oxidation is performed in a high temperature furnace.

13. The method as recited in claim 1, wherein said oxide layer is removed by etching with buffered HF solution.

14. The method as recited in claim 1, wherein said oxide layer is removed by etching with dilute HF solution.

15. The method as recited in claim 1, wherein said substrate is a silicon substrate.

16. The method as recited in claim 1, wherein said oxide layer is removed by plasma etching.

17. The method as recited in claim 1, wherein said oxide is silicon dioxide.

18. An apparatus for removing silicon carbide or low dielectric constant material film, wherein said silicon carbide (SiC) or low dielectric constant (low k) material film is formed on a substrate, the apparatus comprising:
A high temperature processing unit, for process said SiC or low k material film under high temperature oxidation to transform the film to an oxide layer; and
An etching unit, including etch solution for removing said oxide layer.

19. The apparatus as recited in claim 18, wherein said high temperature process unit is a high temperature furnace.

20. The apparatus as recited in claim 18, wherein said high temperature process unit is a rapid thermal processing (RTP) unit.

21. The apparatus as recited in claim 18, wherein said etching unit is a wet bench.

22. The apparatus as recited in claim 18, wherein said high temperature process unit is a single wafer spin etching processor.

23. The apparatus as recited in claim 18, wherein said high temperature oxidation unit and said etching unit are formed in a single apparatus.

24. The apparatus as recited in claim 18, wherein said high temperature process unit and said etching unit are installed separately.

25. The apparatus as recited in claim 18, wherein said high temperature process unit and said etching unit are installed as a cluster tools.
